(19) United States
(12) Patent Application Publication
(10) Pub. No.: US 2003/0093741 A1
(43) Pub. Date: May 15, 2003

(54) Parallel decoder for product codes

(76) Inventors: Cenk Argon, Atlanta, GA (US); Steven William McLaughlin, Decatur, GA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/202,205

(22) Filed: Jul. 24, 2002

Related U.S. Application Data
(60) Provisional application No. 60/333,257, filed on Nov. 14, 2001.

(51) Int. Cl. H03M 13/00

(52) U.S. Cl. 714/755

(57) ABSTRACT

A system is described for decoding product codes. The system includes logic configured to pass reliability determinations made while decoding symbols using first parity information, to use in decoding the symbols using second parity information, while substantially simultaneously passing the reliability determinations made while decoding the symbols using the second parity information, to use in decoding the symbols using the first parity information.

### CROSS-REFERENCE TO RELATED APPLICATION

This application claims priority to copending U.S. provisional application entitled, “A PARALLEL DECODER FOR LOW LATENCY DECODING OF TURBO PRODUCT CODES,” having ser. No. 60/333,257, filed Nov. 14, 2001, which is entirely incorporated herein by reference.

### TECHNICAL FIELD

The present invention is generally related to error correction coding, and, more particularly, is related to a system and method for decoding product codes.

### BACKGROUND OF THE INVENTION

Communication systems generally employ error correction coding to reduce the need for re-transmitting data. For example, when some systems, such as the Internet, detect errors at the receiver end, they re-transmit. One problem with this scheme is that retransmission also produces increased latency in a communications system. Many varieties of error correction schemes exist. For example, data can be sent with added bits, or overhead, that include a repetition code, such as 3 bits of value zero (e.g., 0 0 0). At the receiving end, if two of the three bits are zero and one bit was corrupted (e.g. “flipped”) in the transmission, one error correcting code mechanism employed could be that the majority rules, and the correction will be to change the bit from a “1” value to a “0” value. One problem with repetition coding is that of added overhead, which can result in increased decoding latency.

Thus, one goal in error correction coding is to reduce the need for retransmissions, yet provide error free communication. In providing such communications, decoders have been developed to process successive iterations of error correction algorithms to find errors and correct them for sometimes vast amounts of data, such as those found in video, audio, and/or data transmissions. With improvements in digital signal processing, decoders are being pressed to handle even greater amounts of data, unfortunately often with increased processing latency. Thus, a need exists in the industry to address the aforementioned and/or other deficiencies and inadequacies.

### SUMMARY OF THE INVENTION

The preferred embodiments of the present invention include, among others, a system for decoding product codes. The system includes logic configured to pass reliability determinations made while decoding symbols using first parity information, to use in decoding the symbols using second parity information, while substantially simultaneously passing reliability determinations made while decoding the symbols using the second parity information, to use in decoding the symbols using the first parity information.

The preferred embodiments of the present invention also include, among others, a method for decoding product codes. The method can generally be described by the following steps: determining the reliability of symbols that were encoded using first parity information and second parity information; and passing the reliability determinations made while decoding the symbols using the first parity information, to use in decoding the symbols using the second parity information, while substantially simultaneously passing the reliability determinations made while decoding the symbols using the second parity information, to use in decoding the symbols using the first parity information.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1A is a block diagram of one example communication system that includes an example parallel decoding system (PDS) that employs error correction mechanisms, in accordance with one embodiment of the invention.

FIG. 1B is a schematic diagram of select internal circuitry of one embodiment of the example PDS of FIG. 1A.

FIG. 1C is a schematic diagram of select internal circuitry of another embodiment of the example PDS of FIG. 1A.

FIG. 2A is a block diagram of the example product code depicted in FIG. 1A configured in matrix form, in accordance with one embodiment of the invention.

FIGS. 2B-2C are block diagrams of an example product code that has undergone a first iteration of parallel row and column error correcting, in accordance with one embodiment of the invention.

FIG. 3 is a block diagram of one example partial row of the product code of FIG. 2A with symbols in the form of real numbered voltage values, in accordance with one embodiment of the invention.

FIG. 4A is a schematic diagram illustrating the sharing of extrinsic information between row and column decoders of the parallel decoder of the PDS of FIG. 1A, in accordance with one embodiment of the invention.

FIG. 4B is a block diagram illustrating the functionality of the example parallel decoder of the PDS of FIG. 1A and illustrating the extrinsic information transfer as depicted in FIG. 4A, in accordance with one embodiment of the invention.

FIG. 5 is a flow diagram of one example parallel decoding method employed by the example parallel decoding embodiments of FIGS. 1B and 1C, in accordance with one embodiment of the invention.

### DETAILED DESCRIPTION OF THE PREFERRED EMBODIMENTS

The preferred embodiments of the invention now will be described more fully hereinafter with reference to the accompanying drawings. One way of understanding the preferred embodiments of the invention includes viewing them within the context of a communications system, and more particularly within the context of a parallel decoding system (PDS) that includes functionality for substantially simultaneous row and column decoding of product codes. Herein, decoding will be understood to include error detection and/or error correction functionality. Although other systems with data transmitted in other formats are considered to be within the scope of the invention, the preferred embodiments of the invention will be described in the context of a parallel decoder of the PDS that receives symbols preferably encoded in a product code (PC) in a matrix format over a communication medium.

The symbols include data information encoded at one or more encoders. The symbols can be formatted in several forms, including bit or byte format, or preferably as real numbered values. Generally, the product codes described herein include those formats exhibiting characteristics that include some form of error correction or control code iteration, some mechanism for gathering extrinsic information (e.g., information that can be used to determine the reliability of one or more symbol values), and some form of diversity (e.g., independence in row and column decoding operations). Product codes are further defined below.

Because the preferred embodiments of the invention can be understood in the context of a communications system, an initial general description of a communications system is followed by two example hardware and software implementations for the PDS. A description of one PC format for transmitting data throughout the communications system is then described. Following the description of the PC format is an example of some row values of the PC that comprise soft information, or extrinsic information, useful in error correction. Note that extrinsic information will herein be understood to include real numbered values received from the communication medium in addition to reliability information passed between a row and column decoder. An example of the parallel decoding processing of extrinsic information is then described, followed by a block diagram description that illustrates the parallel processing functionality of a parallel decoder of the PDS as it implements this extrinsic information sharing. Finally, an example method for parallel decoding of a PC is described.

The preferred embodiments of the invention may, however, be embodied in many different forms and should not be construed as limited to the embodiments set forth herein; rather, these embodiments are provided so that this disclosure will be thorough and complete, and will fully convey the scope of the invention to those having ordinary skill in the art. Furthermore, all “examples” given herein are intended to be non-limiting, and are provided as an exemplary list among other examples contemplated but not shown.

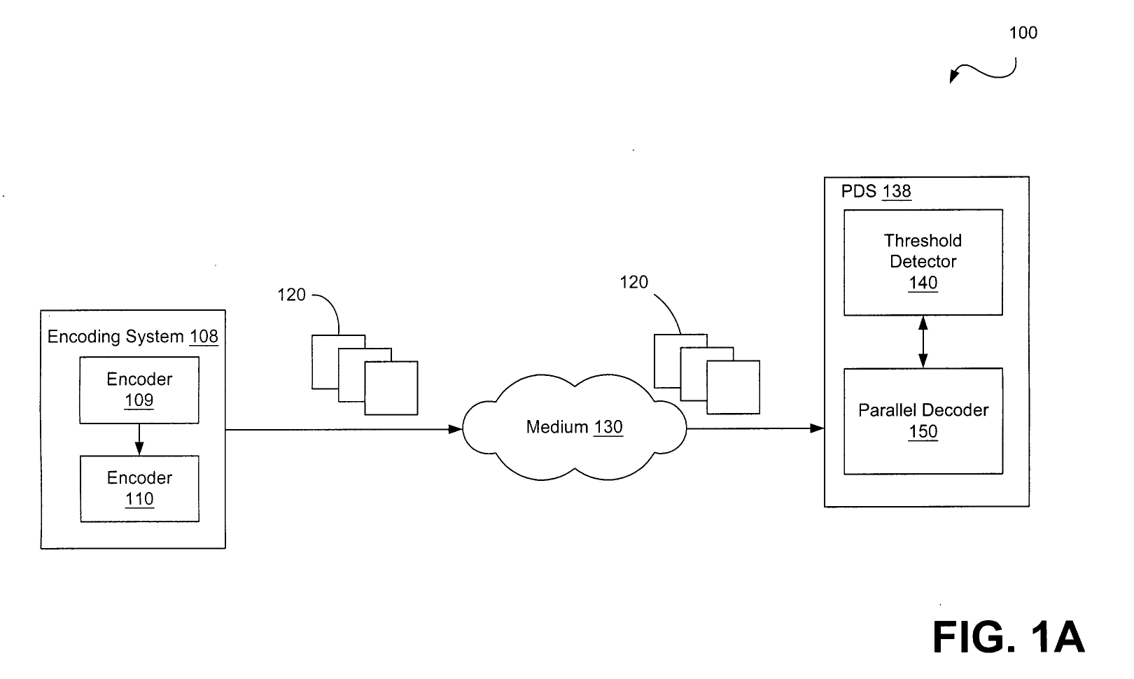

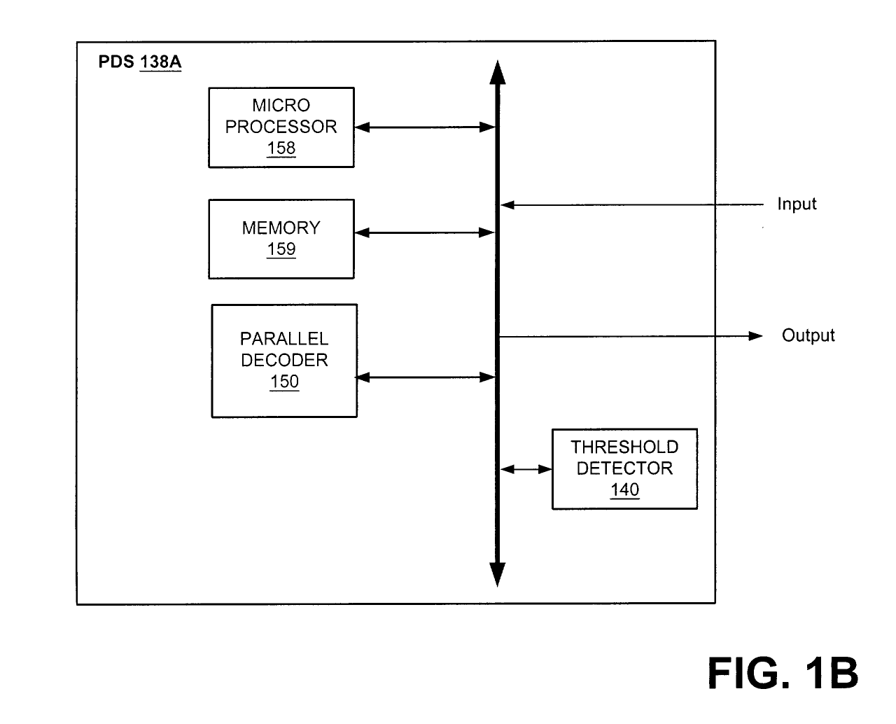

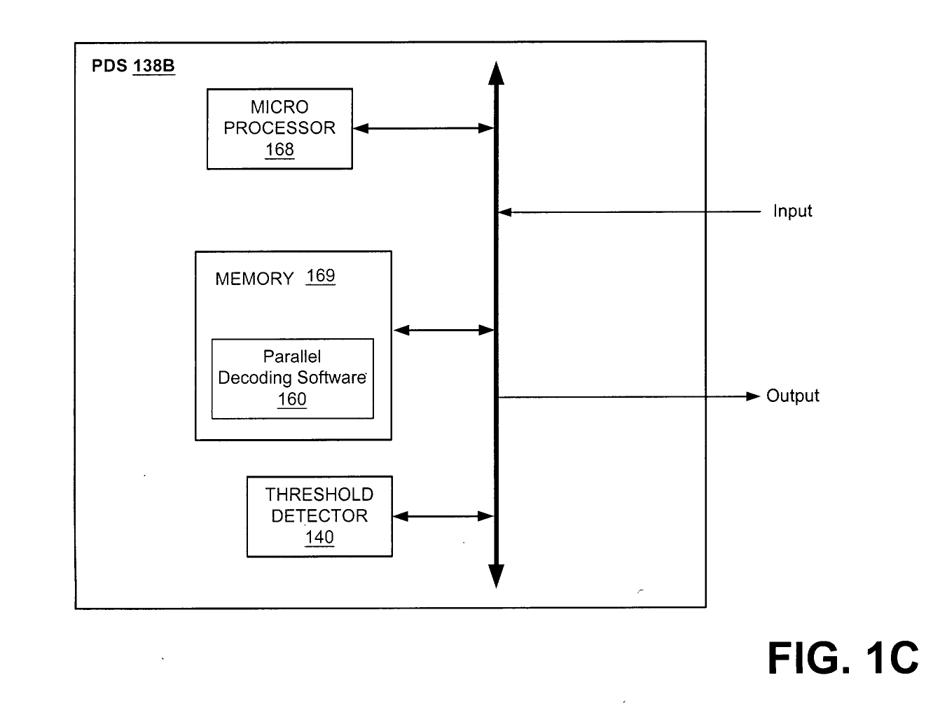

FIG. 1A is a block diagram of one example communication system 100 that employs error correction coding, in accordance with one embodiment of the invention. The example communication system 100 can be implemented as a cable or satellite communication system, or a fiber optic link, or a cellular phone system, among other systems. For example, the communication system 100 can also include systems embodied in a single device, such as a consumer electronics device like a digital video disk (DVD) player, a compact disk (CD) player, or a memory array structure, among other systems and devices where the communication can occur over an internal bus or wiring between encoding and decoding functionality components. As shown, the example communication system 100 includes an encoding system 108, a communication medium 130, and a parallel decoding system (PDS) 138.

The encoding system 108 preferably includes functionality for encoding symbols for transmittal over a communications medium 130, and can be included in such diverse components as a transmitter in a telephone system or in a fiber optic link, or a headend or hub in a cable television system, among other types of systems and devices. The communication medium 130 includes media for providing a conduit for transferring information over a finite distance, including free space, fiber optic, hybrid fiber/coax (HFC), cable, or internal device wiring, among others. The PDS 138 preferably includes functionality for decoding the information transmitted over the communications medium 130, and can be included in such devices as a receiver, a computer or set-top box, or other systems or devices that include decoding functionality and which can provide a direct output to a user and/or transfer information to another component or device.

The encoding system 108 preferably includes functionality to encode data for transfer over the communication medium 130, such as encoders 109 and 110. Generally, information is encoded at encoder 109 with a first level of error correction information (e.g., parity). This information and parity can be ordered into a defined format, or in other embodiments, preferably randomized at encoder 109 and then passed to a second encoder 110 where it is encoded with another level of parity, and then output to the communication medium 130. Herein, this information that is encoded and output to the communication medium 130 will be described as a product code. The product codes will be described herein using a matrix format (e.g., rows and columns of symbols), with the understanding that product codes will not be limited to this matrix format but can take the form of substantially any encoded format used for transmitting data, whether formatted in ordered and/or random fashion.

The PDS 138 preferably includes a parallel decoder 150 and a threshold detector 140, in accordance with one embodiment of the invention. Although shown as separate components, functionality of each component can be merged into a single component in some embodiments. The parallel decoder 150 preferably includes functionality for substantially simultaneous row and column decoding, in accordance with one embodiment of the invention. The parallel decoder 150 preferably receives the information in PCs 120 over the communication medium 130 (i.e., data is sent over the communication medium 130 usually in a serial fashion. For example, symbols (e.g., bits) are read out row-by-row, or column-by-column. At the PDS side, the parallel decoder 150 re-orders the data into the matrix form). In one example implementation, information can be transferred over the communications medium 130 as symbols formatted as voltage levels representing binary 1's and 0's. These voltage levels are preferably inserted into the PCs 120 at the encoders 109 and 110. The information is transferred over the communication medium 130 and received and re-formatted, in one implementation, at the parallel decoder 150.

The parallel decoder 150 decodes the rows and columns of the PCs 120 substantially simultaneously, and uses the information from the communication medium 130 in cooperation with one or more threshold detectors, such as threshold detector 140, to provide error correcting on the information, in accordance with the preferred embodiments of the invention. In one implementation, the threshold detector 140 performs a comparator function where it compares the voltage values received at the parallel decoder 150 to a defined threshold value to provide the parallel decoder 150 with an indication of the proximity of the voltage level to a decided binary value (as decided by the parallel decoder 150). In other implementations, the threshold detector 140 performs more of “threshold” function, where it receives the product codes 120 that have symbols formatted as real numbered values (e.g., voltage values) from the communication medium 130. In this implementation, the threshold detector 140 “thresholds” the received values to bit or byte values, and the parallel decoder 150 operates on these values.

Preferably, the parallel decoder 150 and the threshold detector 140 will operate using a combination of real numbered values and byte and/or bit values during the various stages of decoding. For example, the product codes 120 can carry real numbered voltage values, which are received by the parallel decoder 150. These values can be loaded into the threshold detector 140, which then returns bit values that include values that are “flagged” as unreliable by the parallel decoder 150. The parallel decoder 150 can run error correcting iterations on the bits to provide an update on the reliability of the bits, then use the threshold detector 140 (or another threshold detector) to return the values to updated real numbered values to pass on to a next decoding stage. Note that other components, although not shown, can also be included in the communication system 100, including memory, modulators and demodulators, analog to digital converters, processor, among others as would be understood by one having ordinary skill in the art.

FIGS. 1B-1C are block diagram illustrations of select components of the PDS 138 of FIG. 1A, in accordance with two embodiments of the invention. FIG. 1B illustrates the PDS 138A in which the parallel decoder 150 is implemented as hardware, in accordance with one embodiment. The parallel decoder 150 can be custom made or a commercially available application specific integrated circuit (ASIC), for example, running embedded parallel decoding software alone or in combination with the microprocessor 158. That is, the parallel decoding functionality can be included in an ASIC that comprises, for example, a processing component such as an arithmetic logic unit for handling computations during the decoding of rows and columns. Data transfers to and from memory 159 and/or to and from the threshold device 140 for the various matrices (as explained below) during decoding can occur through direct memory access or via cooperation with the microprocessor 158, among other mechanisms. The microprocessor 158 is a hardware device for executing software, particularly that stored in memory 159. The microprocessor 158 can be any custom made or commercially available processor, a central processing unit (CPU), an auxiliary processor among several processors associated with the parallel decoder 150, a semiconductor based microprocessor (in the form of a microchip or chip set), a macroprocessor, or generally any device for executing software instructions. The threshold detector 140 can be software and/or hardware that is a separate component in the PDS 138A, or in other embodiments, integrated with the parallel decoder 150, or still in other embodiments, omitted from the PDS 138 and implemented as an entity separate from the PDS 138 yet in communication with the PDS 138. The PDS 138 can include more components or can omit some of the elements shown, in some embodiments.

In one preferred embodiment, where the parallel decoder 150 is implemented in hardware, the parallel decoder 150 can be implemented with any or a combination of the following technologies, which are each well known in the art: a discrete logic circuit(s) having logic gates for implementing logic functions upon data signals, an ASIC having appropriate combinational logic gates, a programmable gate array(s) (PGA), a field programmable gate array (FPGA), etc.

FIG. 1C describes another embodiment, wherein parallel decoding software 160 is embodied as a programming structure in memory 169, as will be described below. The memory 169 can include any one or combination of volatile memory elements (e.g., random access memory (RAM, such as DRAM, SRAM, SDRAM, etc.)) and nonvolatile memory elements (e.g., ROM, hard drive, tape, CDROM, etc.). Moreover, the memory 169 may incorporate electronic, magnetic, optical, and/or other types of storage media. Note that the memory 169 can have a distributed architecture, where various components are situated remote from one another, but can be accessed by the microprocessor 168.

In one implementation, the software in memory 169 can include parallel decoding software 160, which provides executable instructions for implementing the matrix decoding operations. The software in memory 169 may also include one or more separate programs, each of which comprises an ordered listing of executable instructions for implementing logical functions and operating system functions such as controlling the execution of other computer programs, providing scheduling, input-output control, file and data management, memory management, and communication control and related services.

When the PDS 138 (embodiments 138A or 138B) is in operation, the microprocessor 158 (or 168) is configured to execute software stored within the memory 159 (or 169), to communicate data to and from the memory159 (or 169), and to generally control operations of the PDS 138A, 138B pursuant to the software.

When the parallel decoding functionality is implemented in software, it should be noted that the parallel decoding software 160 can be stored on any computer readable medium for use by or in connection with any computer related system or method. In the context of this document, a computer readable medium is an electronic, magnetic, optical, or other physical device or means that can contain or store a computer program for use by or in connection with a computer related system or method.

The parallel decoding software 160 and/or the parallel decoder 150 can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can store, communicate, propagate, or transport the program for use by or in connection with the instruction execution system, apparatus, or device. The computer readable medium can be, for example but not limited to, an electronic, magnetic, optical, electromagnetic, infrared, or semiconductor system, apparatus, device, or propagation medium.

More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM, EEPROM, or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory. In addition, the scope of the present invention includes embodying the functionality of the preferred embodiments of the present invention in logic embodied in hardware and/or software configured mediums.

The descriptions that follow (along with the accompanying drawings) will focus on the hardware embodiment (FIG. 1B) wherein the parallel decoding functionality is implemented via the parallel decoder 150 (FIG. 1B) of the PDS 138 (FIG. 1A), with the understanding that row and column decoding functionality will similarly apply when the software embodiment (FIG. 1C) is employed. Further, it will be understood that the parallel decoder 150 preferably acts in cooperation with other elements of the PDS 138 to provide parallel decoding functionality.

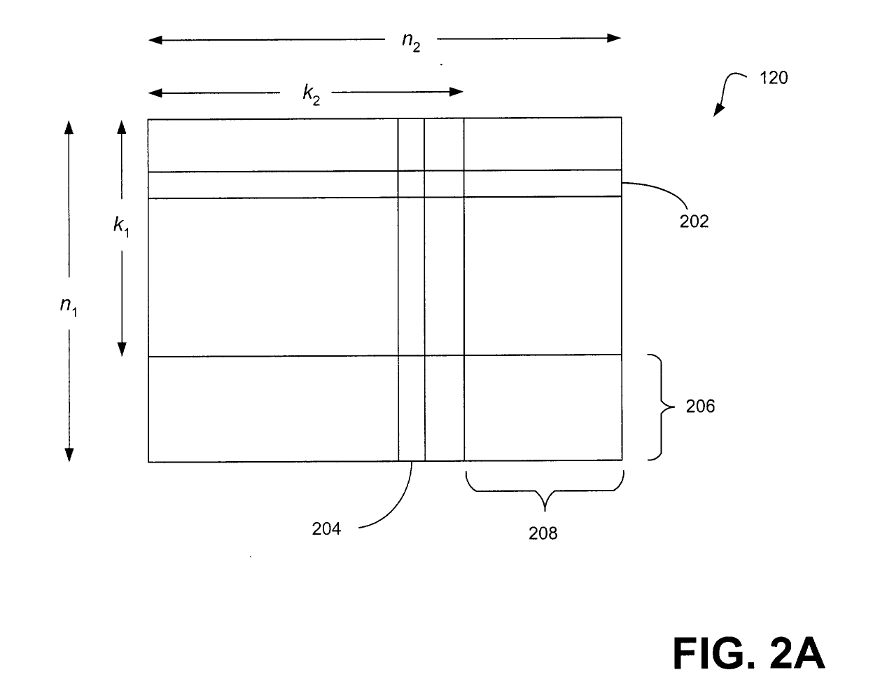

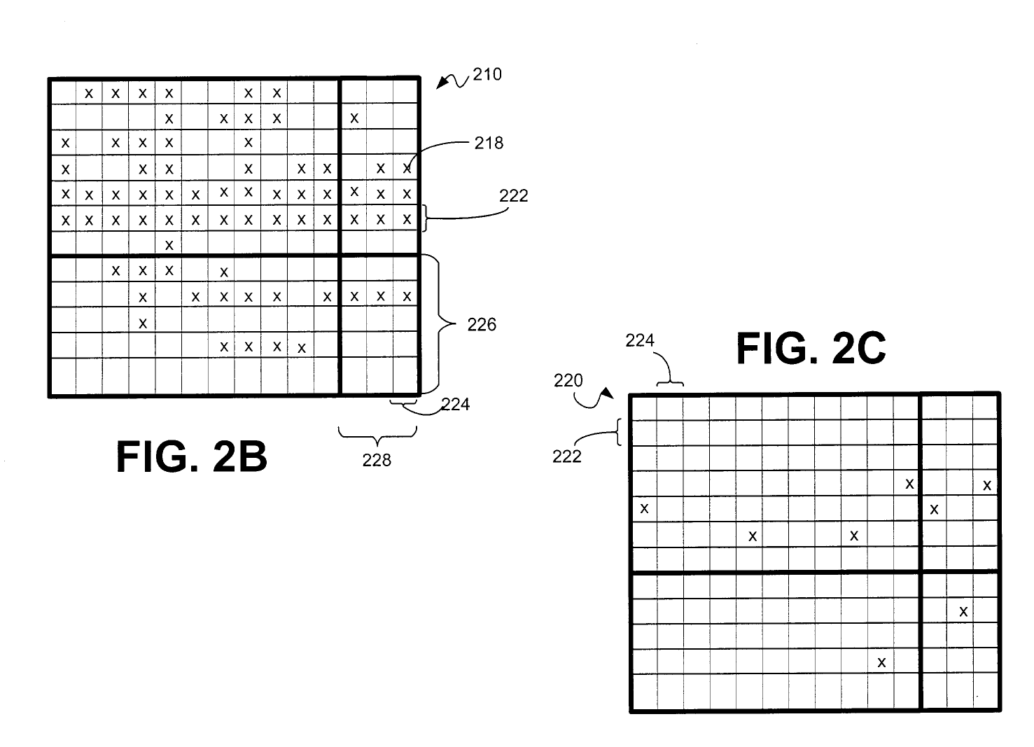

FIG. 2A is a block diagram of the example PC 120 depicted in FIG. 1A, in accordance with one embodiment of the invention. As described above, the encoding and transferring of information as symbols in a matrix arrangement is not a limitation of the preferred embodiments of the invention, and other arrangements are possible, including random configurations that use random generators and data structures to store and track where error detection and correction has been implemented, among others. Preferably, symbols are inserted at the encoders 109 and 110 (FIG. 1A) in a 2-dimensional array that includes rows 202 and columns 204 of symbols. Note that only one row 202 and column 204 is depicted, with the understanding that arrays of various quantities of rows and columns can be employed and be considered within the scope of the invention. Parity row areas 206 and parity column areas 208 include symbols that are added at the encoders 109 and 110 through algorithms, such as those well known in the art, resulting in row parity, column parity, and parity on parity. Symbols can be read into the array in the form of bits or bytes or real numbered values.

PCs 120 (FIG. 2A) in a matrix format can be represented mathematically. In general, the two-dimensional PC 120 is obtained as follows: the information symbols are initially arranged in a k₁×k₂ array. Then, the columns are encoded using a linear block code C₁ (n₁, k₁, δ₁). Afterwards, the resulting n₁ rows are encoded using a linear block code C₂ (n₂, k₂, δ₂) and the PC 120, which consists of n₁ rows and n₂ columns is obtained. The parameters of code C₁ (i=1,2), denoted as n₁, k₁, and δ₁, are the codeword length, number of information symbols, and minimum Hamming distance, respectively. Codes C₁ and C₂ are called the constituent (or component) codes. The parameters of the resultant PC 120 are n_{C}=n₁n₂, k_{C}=k₁k₂, δ_{C}=δ₁δ₂, and the code rate is R_{C}=R₁R₂, where Rᵢ=kᵢ/nᵢ. To decrease implementation complexity of the encoders 109 and 110 (FIG. 1A) and the parallel decoder 150 (FIG. 1A), preferably the same block code is selected as the row and column constituent code (i.e., C₁=C₂).

As one example implementation of how the parallel decoder 150 can perform error correcting on a product code, from a higher level perspective, assume a high-speed implementation such as decoding for a DVD application. FIG. 2B is a block diagram of an example PC 210 for a DVD application. A product code for the DVD is preferably byte oriented. Assume the DVD has a section of about say 1-2 millimeters in length that is scratched, as well as having other errors (as denoted by the x's 218 in the rows 222 and columns 224). Assume the row parity 226 and column parity 228 will allow correction of up to 3 bytes of error per row 222 and per column 224. Note that each square represents one byte of information, but in other implementations, may represent one bit of information.

FIG. 2C illustrates the result of one example iteration of parallel row and column decoding on the product code 210 (FIG. 2B). As shown, the rows 222 and columns 224 of the resultant product code 220 that had 3 or fewer errors were corrected completely, while those that had greater numbers of errors had some residual errors that would preferably be corrected in a second iteration. The number of decoding iterations performed can be limited according to several mechanisms or system constraints. In one embodiment, the parallel decoder 150 (FIG. 1A) can terminate iterations at a particular symbol position in a row or column when the parallel decoder 150 has decided that the symbol is reliable enough (e.g., within a certain proximity to 0.0V or 5.0V and/or “far enough” from a threshold value). Other constraints on iterations can include system design parameters, such as the processing time the parallel decoder 150 is allowed per block, or array, of data. Other constraints include errors that are so significant that they overwhelm the parallel decoder 150, or error patterns may cause detectable error correcting problems. In the latter implementations, the parallel decoder 150 may request a retransmission (or in data storage applications, may cause a re-reading of the data).

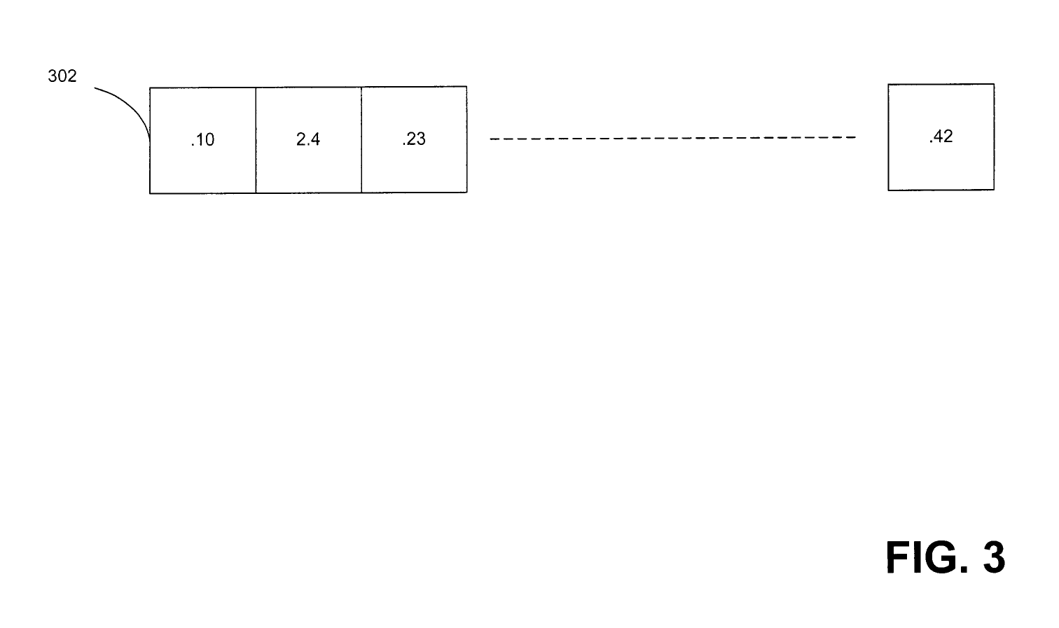

The preferred embodiments of the invention include a parallel decoder 150 (FIG. 1A) that comprises at least one row decoder (not shown) and at least one column decoder (not shown). The parallel decoder 150 preferably shares extrinsic information between the row decoder and the column decoder during substantially simultaneous decoding operations. This extrinsic information preferably is manifested in real number values, such as voltage levels received from the communications medium 130 (FIG. 1A) and updated by the row decoder (or column decoder) to indicate an improved or decreased reliability. FIG. 3 includes an example partial row 302 of real number valued voltages from the PC 120 (FIG. 2A). During decoding operations, in one implementation, this row can have unreliable values updated to reliable values, and reliable values will be used to generate another array comprising bit values for the real numbered voltage values.

The parallel decoder 150 (FIG. 1A) preferably handles three arrays of data: (i) real numbered voltage data received from the communication medium 130 (FIG. 1A), (ii) generated bit values based on the voltage data, and (iii) revised voltage data that the row decoder of the parallel decoder 150 will pass to the column decoder (and vice versa) for substantially simultaneous row (and column) decoding in a first iteration, and then subsequent iterations. Although the descriptions accompanying FIG. 3 emphasize decoding operations from the perspective of a row decoder, it will be understood that mirrored, yet independent, operations will occur at the column decoder. Looking at the example row 302, a few example voltage values are given which represent a sampled signal received from the communication medium 130. In one implementation, before row decoding even begins, the parallel decoder 150 has an indication of the reliability of the received voltage values.

For example, the first row position has a value of 0.1V. As bit values are typically transferred over a medium using voltage values that represent 1's and 0's, assume that the value of 1 is represented with a voltage value of approximately 5.0V, and the bit value of 0 is represented with approximately 0.0V. Assume a threshold value configured at the threshold detector 140 (FIG. 1A) of 2.5V. The parallel decoder 150 (FIG. 1A) recognizes that the 0.1V is very close to zero. Receiving input from the threshold detector 140, as shown in FIG. 1A, the parallel decoder 150 determines that the first voltage value is also much less than the threshold value. Voltage values with a high degree of reliability will preferably be updated to make the values more reliable and then they are passed to the column decoder of the parallel decoder 150 where further error correcting is employed, preferably independent of the row decoding. Voltage values with a low degree of reliability (e.g., near the threshold value) will also be updated, and that updated value will be used in column decoding.

Looking at the voltage value of the next row position, the parallel decoder 150 (FIG. 1A) recognizes that there may be a reliability issue with this value, since 2.4V, although closer to 0.0V than 5.0 volts, is “near” the 2.5V voltage threshold of the threshold detector 140 (FIG. 1A), and thus this voltage value is “flagged” as suspect. The parallel decoder 150 can proceed to run an algorithm to evaluate many different permutations of values for this unreliable value (and others that follow) to determine an updated value that will be passed to the column decoder to improve (or reduce) the reliability of the voltage value for column decoding. Note that further information on some algorithms employed to update values can be found in the references entitled, “Near-optimum decoding of product codes: Block turbo codes,” IEEE Trans. Commun., vol. 46, no. 8, pp. 1003-1010, August 1998, and D. Chase, “A class of algorithms for decoding block codes with channel measurement information,” IEEE Trans. Inform. Theory, vol. IT-18, no. 1, pp. 170-182, January 1972, and the patent entitled, “Process for Transmitting Information Bits with Error Correction Coding and Decoder for the Implementation of this Process, having U.S. Pat. No. 6,122,763, filed Aug. 28, 1997, all of which are herein incorporated by reference in their entirety.

If the parallel decoder 150 (FIG. 1A), through running various permutations, determines a value that indicates the generated bit value should be zero and not one, then the row decoder of the parallel decoder 150 preferably updates the value of 2.4V with a new value. The new value is preferably more indicative of a 0 bit value, say 2.0V, for example, to provide a voltage value to the column decoder of the parallel decoder 150 that is more reliable. Note that the column decoder may process this symbol position and determine that the value is more indicative of a binary “1”, and thus a “reliability tug-of-war” between row and column decoding can occur through several iterations. Thus, even before the decoding process begins, the parallel decoder 150 has information about which symbols are unreliable and which symbols are reliable, based on the voltage level from the communication medium 130 (FIG. 1A) and its proximity to the defined threshold value configured at the threshold detector 140 (FIG. 1A), or elsewhere.

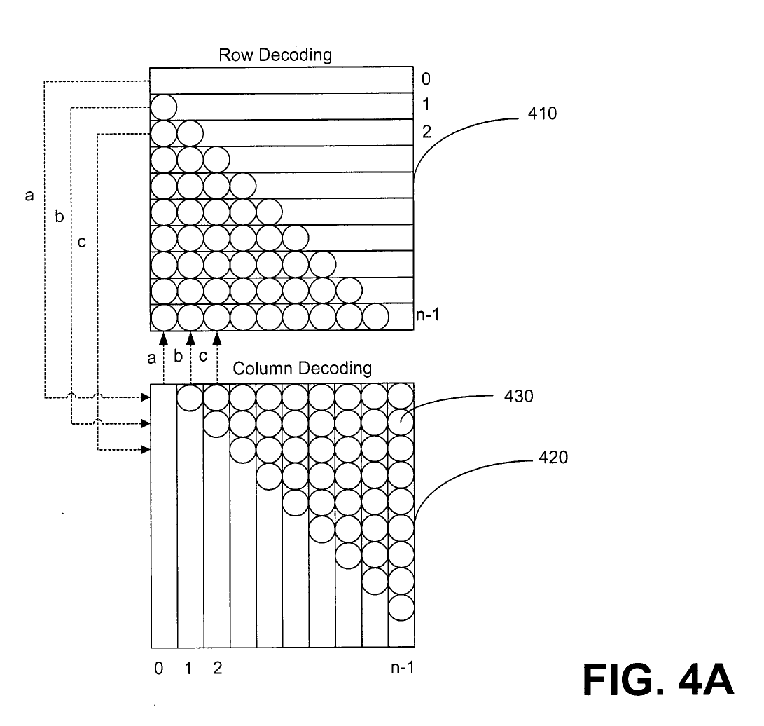

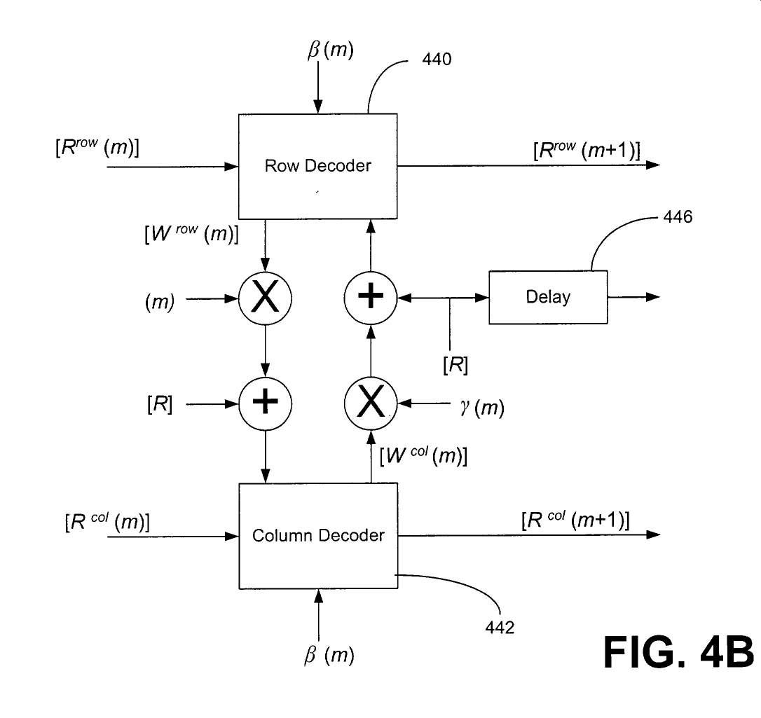

As indicated above, the row decoding and the column decoding preferably occur substantially simultaneously, and the row decoder of the parallel decoder 150 (FIG. 1A) updates the PC arrays based on the extrinsic information received from the communication medium 130 (FIG. 1A) and passes the updated values to the column decoder, and vice versa. FIG. 4A illustrates this passing of extrinsic information, in accordance with one embodiment of the invention. The top box 410 represents row decoding operations, and the bottom box 420 represents column decoding operations, both which the parallel decoder 150 will perform in parallel, as described above. As shown, decoding of rows and columns proceeds with parallel updates of each decoder component (i.e., updates to the row decoder are contemporaneous with the updates to the column decoder). The circles 430 denote already updated symbol positions during decoding of a particular row or column. The letters “a”, “b”, and “c” denote the order of information transfer between the decoders, with “a” occurring first, “b” occurring second, etc. Assuming a diagonal line from the upper left corner to the lower right corner of the array, the row decoder has updated information about the lower triangular part of the array, whereas the column decoder has information about the upper triangular part (i.e., excluding the symbol positions on the diagonal, the row and column decoders complement each other). At a time corresponding to when the row and column decoders have finished decoding all rows and columns, respectively, each respective row and column decoder passes updated matrices as inputs to the next decoding stage.

This process of using real number information from the communication medium to update the reliability and pass the reliability determinations between decoders during decoding (described as iterative soft decision decoding of product codes) can generally be described mathematically. With continued reference to FIG. 2A, the parallel decoder 150 (FIG. 1A) preferably applies a Chase algorithm iteratively on the rows and columns of the PC 120 (FIG. 2A). The Chase algorithm is a sub-optimum decoding method based on forming test patterns using channel (e.g., communication medium) information and passing these test patterns through an algebraic decoder for the employed block code. These test patterns are formed by perturbing the p least reliable symbol positions (p being a fixed or variable design parameter that is preferably experimentally determined) in the received noisy sequence (p is selected as p<<k). The number of test patterns is equal to 2^{p}. After decoding of the test patterns, the most likely among the generated candidate codewords is assigned as the decided codeword.

The reliability information for symbol position j is expressed in terms of a log-likelihood ratio (LLR) given by:

Λ(dⱼ)=log[(Pr(cⱼ=+1|R))/(Pr(cⱼ=−1|R))], (Eq. 1)

where D=d₀ . . . dₙ₋₁ (dⱼ ε{0, 1}) is the decided codeword after Chase decoding, R=r₀, . . . rₙ₋₁ denotes the received noisy sequence, and C=c₀ . . . cₙ₋₁ is the transmitted codeword. If \hat{D}=\hat{d}₀ . . . \hat{d}ₙ₋₁ (if it exists) is the most likely competing codeword among the candidate codewords with \hat{d}ⱼ≠dⱼ, then for a stationary additive white Gaussian noise (AWGN) communication medium and a communication system using binary phase shift keying (BPSK), for example, the LLR of symbol position j can be approximated by:

Λ(dⱼ)≈[(|R−\hat{D}|²−|R−D|²)/4](2dⱼ−1), (Eq. 2)

where |A−B|² denotes the squared Euclidean distance between vectors A and B. Equation 2 is essentially describing how the new information (e.g., the updated voltage value) is computed. The extrinsic information wⱼ for the jth position (e.g., the updated voltage values (symbol entries in the arrays) that are passed to the column decoder, and vice versa) is found by:

wⱼ={Λ(dⱼ)−rⱼ, if a competing \hat{D} exists, or β(2dⱼ−1), if no competing \hat{D} exists}, (Eq. 3)

where β is a reliability factor. Once the extrinsic information has been determined, the input to the next decoding stage is updated as

r′ⱼ=rⱼ+γwⱼ, (Eq. 4)

where γ is a weight factor introduced to combat high bit error rate (BER) and high standard deviation in wⱼ during the first iterations. In other words, for the example implementation described above, the new r′ⱼ in a next stage decoding is the old rⱼ (i.e., the initial voltage value received from the communication medium 130 (FIG. 1A) and entered at a position in the PC array) plus a weighted updated voltage value. Preferably, γ is an experimentally determined value. The operations above are performed on all symbols of a product codeword, hence equation 4 can be expressed as

[R′]=[R]+γ[W]. (Eq. 5)

Note that the preferred embodiments of the invention are not limited to reliability determinations according to the mechanism described above. For example, the reliability determinations can be made by using an inner product metric instead of the squared Euclidean distance metric described above (Eq. 2). The LLR of symbol position j can be evaluated, in terms of the inner product metric as,

Λ(dⱼ)=[(R·D−R·\hat{D})/2](2dⱼ−1), (Eq. 6)

where dⱼ ε{0,1}. Further information regarding this mechanism for reliability determinations can be found in the commonly assigned patent application entitled, “Efficient Decoding of Product Codes”, filed on the same date under attorney docket no. 62020.1090, and assigned to Georgia Tech, which is herein incorporated by reference.

A schematic diagram that illustrates the functionality of the example parallel decoder 150 (FIG. 1A) at one stage is shown in FIG. 4B, in accordance with one embodiment of the invention. As shown, the prior equations are somewhat reflected in the schematic. The example parallel decoder includes at least one row decoder 440 and a column decoder 442. The row and column decoders 440 and 442 operate here in parallel and update each other contemporaneously with a row or column decoding. Furthermore, only one delay element 446 is utilized thus providing a benefit of reduced decoding latency versus conventional serial decoding systems. For example, in some implementations, the decoding time is halved when compared to some prior art decoding mechanisms, while the performance is virtually preserved. Relating the above math formulations to the parallel decoder of FIG. 4B, the integer “m” denotes the number of the current full iteration. The [R] represents that the channel information (e.g., real number valued voltage) is used for each decoding and for each iteration. [R^{row}] and [R^{col}] in the first iteration are equal to [R], but once updated, the [R^{row}] includes the updated extrinsic information received from the column decoder (γ×[W^{col}]) and the [R^{col}] includes the updated extrinsic information received from the row (γ×[W^{row}]) to be passed to the next iteration, along with the [R] channel information. The matrices [W^{row}] and [W^{col}] are the row and column extrinsic information matrices, respectively, and are transferred on a row-row or column-column basis.

The m^{th} iteration of the row decoding process generates extrinsic information (e.g., updated voltage values) represented by [W^{row}]. Substantially simultaneously, the column decoder 442 generates, on the m^{th} iteration, extrinsic information [W^{col}]. These matrices are preferably scaled by γ, which is preferably a function of the iteration, producing a scaling effect that increases, as the iterations continue, to one. Following the scaling, (γ×W), the scaled value is added to the original received values R (e.g., the initial voltage values of the product code array received from the communication medium 130 (FIG. 1A)) which gets fed to the respective column 442 or row decoder 440. Once this occurs for an entire PC array, the new R (and old R) is passed on to the block again for the m^{th}+1 iteration (i.e., the next iteration).

In one implementation, the m^{th}+1 iteration is fed back to the row and column decoder 440 and 442. In other implementations, the block diagram of FIG. 4B is replicated for the m^{th}+1 iteration. Because the first iteration for decoding the rows and columns takes a finite amount of time, there is a delay between iterations, as depicted by the delay element 446. This is in contrast to the delays experienced in sequential decoding, which typically include a first delay until the first iteration of the row decoding has occurred, and then a second delay until the first iteration of the column decoding has occurred.

Note that β is a reliability factor, as explained above, which is essentially a scaling factor that handles circumstances where the row and/or column decoder cannot implement decoding.

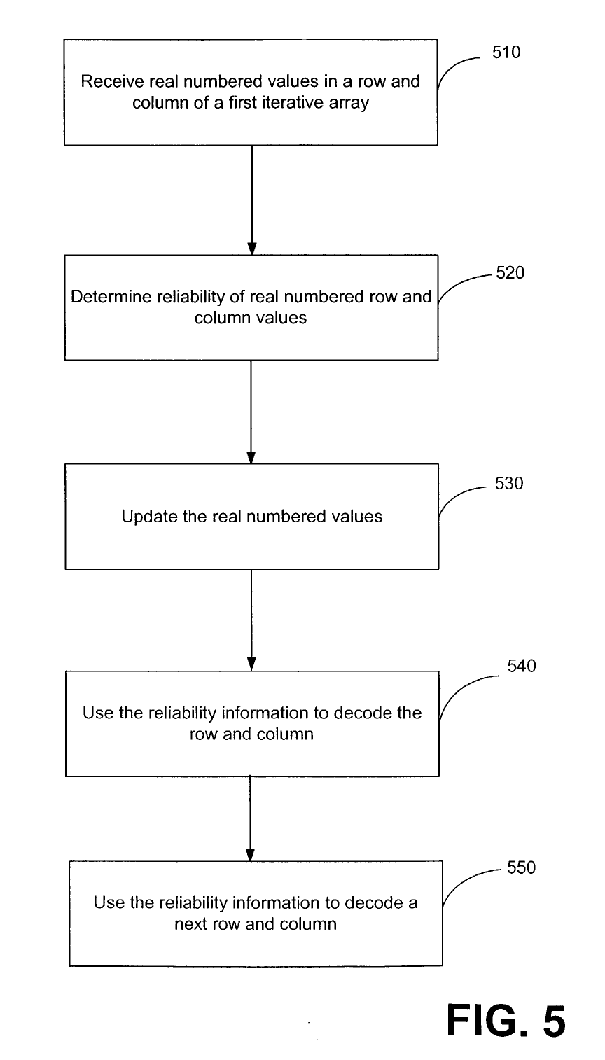

FIG. 5 is a flow diagram illustrating one example method that can be implemented by the decoder 150 of FIG. 1B, or via the parallel decoding software 160 of FIG. 1C, in accordance with one embodiment of the invention. The flow diagram of FIG. 5 shows the architecture, functionality, and/or operation of a possible implementation of the parallel decoder and/or the parallel decoder software. In this regard, each block represents a module, segment, or portion of code, which comprises one or more executable instructions for implementing the specified logical function(s). It should also be noted that in some alternative implementations, the functions noted in the blocks may occur out of the order noted in FIG. 5. For example, two blocks shown in succession in FIG. 5 may in fact be executed substantially concurrently or the blocks may sometimes be executed in the reverse order, depending upon the functionality involved, as will be further clarified hereinbelow.

Step 510 includes receiving a real-numbered signal value in a row and a column of a first iterative array. Step 520 includes determining the reliability of the real numbered signal value of the row and the column. Step 530 includes updating the real numbered signal value of the row and/or the column. Step 540 includes using the information about the reliability of the real numbered signal value to decode the row and the column of the first iterative array. Step 550 includes using the information about the reliability of the real numbered signal value to decode a next row and column of the first iterative array.

It should be emphasized that the above-described embodiments of the present invention, particularly, any “preferred” embodiments, are merely possible examples of implementations, merely set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure and the present invention and protected by the following claims.

Therefore, having thus described the invention, at least the following is claimed:

1. A method for decoding product codes, the method comprising the steps of:
decoding a row of symbols in a product code; and
decoding a column of symbols in a product code while decoding the rows of symbols in the product code.

2. The method of claim 1, wherein the symbols include at least one of real numbered values, real numbered voltage values, bit values, and byte values.

3. The method of claim 1, wherein the product codes include symbols encoded with error correcting codes formatted in a matrix of rows and columns.

4. The method of claim 1, further including the step of determining the reliability of the row symbols and the column symbols based at least in part on real number valued information received from the symbols.

5. The method of claim 4, further including the step of passing the reliability determinations of the row symbols to decode a next column of symbols while passing the reliability determinations of the column symbols to decode a next row of symbols.

6. The method of claim 4, further including the step of using the reliability determinations of the row symbols to decode a next column of symbols while using the reliability determinations of the column symbols to decode a next row of symbols.

7. The method of claim 4, wherein the step of determining the reliability includes the step of calculating a result for the log likelihood ratio according to at least one of equations Λ(dⱼ)≈[(|R−\hat{D}|²−|R−D|²)/4](2dⱼ−1) and Λ(dⱼ)=[(R·D−R·\hat{D})/2](2dⱼ−1) for dⱼ ε{0,1}, wherein R includes a received noisy sequence, D includes a decided codeword after decoding, and \hat{D} includes a candidate codeword.

8. The method of claim 1, wherein the step of decoding includes at least one of error detecting and error correcting.

9. The method of claim 1, wherein the steps of decoding occur for multiple iterations.

10. A method for decoding product codes, the method comprising the steps of:
determining the reliability of row symbols and column symbols for a decoded row and a decoded column based at least in part on real number valued information received from the symbols; and
passing the reliability determinations of the row symbols to decode a next column of symbols at a time corresponding to passing the reliability determinations of the column symbols to decode a next row of symbols, wherein the row and column decoding occur substantially simultaneously.

11. The method of claim 10, wherein the symbols include at least one of real numbered values, real numbered voltage values, bit values, and byte values.

12. The method of claim 10, wherein the product codes include symbols encoded with error correcting codes formatted in a matrix of rows and columns.

13. The method of claim 10, wherein the steps of determining and passing occur for multiple iterations.

14. The method of claim 10, wherein the step of determining the reliability includes the step of calculating a result for the log likelihood ratio according to at least one of equations Λ(dⱼ)≈[(|R−\hat{D}|²−|R−D|²)/4](2dⱼ−1) and Λ(dⱼ)=[(R·D−R·\hat{D})/2](2dⱼ−1) for dⱼ ε{0,1}, wherein R includes a received noisy sequence, D includes a decided codeword after decoding, and \hat{D} includes a candidate codeword.

15. The method of claim 10, wherein the step of passing the reliability determinations of the row symbols and the column symbols occurs substantially simultaneously.

16. A method for decoding product codes, the method comprising the steps of:
decoding a row of symbols while decoding a column of symbols in a product code;
determining the reliability of the row symbols and the column symbols based at least in part on real number valued information received from the symbols;
passing the reliability determinations of the row symbols to decode a next column of symbols at a time corresponding to passing the reliability determinations of the column symbols to decode a next row of symbols; and
decoding the next row of symbols using the reliability determinations of the column symbols while decoding the next column of symbols using the reliability determinations of the row symbols.

17. The method of claim 16, wherein the symbols include at least one of real numbered values, real numbered voltage values, bit values, and byte values.

18. The method of claim 16, wherein the product codes include symbols encoded with error correcting codes formatted in a matrix of rows and columns.

19. The method of claim 16, wherein the step of decoding includes at least one of error correcting and error detecting.

20. The method of claim 16, wherein the steps of decoding, determining, passing, and decoding occur for multiple iterations.

21. The method of claim 16, wherein the step of determining the reliability includes the step of calculating a result for the log likelihood ratio according to at least one of equations Λ(dⱼ)≈[(|R−\hat{D}|²−|R−D|²)/4](2dⱼ−1) and Λ(dⱼ)=[(R·D−R·\hat{D})/2](2dⱼ−1) for dⱼ ε{0,1}, wherein R includes a received noisy sequence, D includes a decided codeword after decoding, and \hat{D} includes a candidate codeword.

22. The method of claim 16, wherein the step of passing the reliability determinations includes passing the reliability determinations of the row symbols to decode a next column of symbols substantially simultaneously with passing the reliability determinations of the column symbols.

23. A method for decoding product codes, the method comprising the steps of:
receiving symbols encoded with first parity information and second parity information; and
decoding the symbols using the first parity information while decoding the symbols using the second parity information.

24. A method for decoding product codes, the method comprising the steps of:
determining the reliability of symbols that were encoded using first parity information and second parity information, wherein the determination is based at least in part on real number valued information received from the symbols; and
passing the reliability determinations, made while decoding the symbols using the first parity information, to use in decoding the symbols using the second parity information, while substantially simultaneously passing the reliability determinations made, while decoding the symbols using the second parity information, to use in decoding the symbols using the first parity information.

25. A system for decoding product codes, the system comprising:
logic configured to decode a row of symbols in a product code, wherein the logic is further configured to decode a column of symbols in a product code while decoding the rows of symbols in the product code.

26. The system of claim 25, wherein the symbols include at least one of real numbered values, real numbered voltage values, bit values, and byte values.

27. The system of claim 25, wherein the product codes include symbols encoded with error correcting codes formatted in a matrix of rows and columns.

28. The system of claim 25, wherein the logic is further configured to determine the reliability of the row symbols and the column symbols based at least in part on real number valued information received from the symbols.

29. The system of claim 28, wherein the logic is further configured to use the reliability determinations of the row symbols to decode a next column of symbols while passing the reliability determinations of the column symbols to decode a next row of symbols.

30. The system of claim 28, wherein the logic is further configured to use the reliability determinations of the row symbols to decode a next column of symbols while using the reliability determinations of the column symbols to decode a next row of symbols.

31. The system of claim 28, wherein the logic is further configured to determine the reliability by calculating a result for the log likelihood ratio according to at least one of equations Λ(dⱼ)≈[(|R−\hat{D}|²−|R−D|²)/4](2dⱼ−1) and Λ(dⱼ)=[(R·D−R·\hat{D})/2](2dⱼ−1) for dⱼ ε{0,1}, wherein R includes a received noisy sequence, D includes a decided codeword after decoding, and \hat{D} includes a candidate codeword.

32. The system of claim 25, wherein the logic is further configured to perform at least one of error correction and error detection of the product code.

33. The system of claim 25, wherein the logic is further configured to decode for multiple iterations.

34. The system of claim 25, wherein the logic is included in at least one of a discrete logic circuit having logic gates for implementing logic functions upon data signals, an application specific integrated circuit having combinational logic gates, a programmable gate array, and a field programmable gate array.

35. The system of claim 25, wherein the logic includes software with parallel decoding functionality.

36. The system of claim 25, wherein the logic includes a row decoder and a column decoder.

37. The system of claim 25, wherein the logic is included in a computer readable medium.

38. The system of claim 25, further including at least one of a processor, memory, and a threshold device that communicates with the logic in providing decoding functionality.

39. The system of claim 38, wherein the processor and the logic are located in separate devices.

40. The system of claim 38, wherein the processor and the logic are located in the same device.

41. A system for decoding product codes, the system comprising:
logic configured to decode a row of symbols while decoding a column of symbols in a product code, wherein the logic is further configured to determine the reliability of the row symbols and the column symbols based at least in part on real number valued information received from the symbols, wherein the logic is further configured to pass the reliability determinations of the row symbols to decode a next column of symbols at a time corresponding to passing the reliability determinations of the column symbols to decode a next row of symbols, wherein the logic is further configured to decode the next row of symbols using the reliability determinations of the column symbols while decoding the next column of symbols using the reliability determinations of the row symbols.

42. The system of claim 41, wherein the symbols include at least one of real numbered values, real numbered voltage values, bit values, and byte values.

43. The system of claim 41, wherein the product codes include symbols encoded with error correcting codes formatted in a matrix of rows and columns.

44. The system of claim 41, wherein the logic is further configured to perform at least one of error correction and error detection of the product codes.

45. The system of claim 41, wherein the logic is further configured to decode, determine, pass, and decode for multiple iterations.

46. The system of claim 41, wherein the logic is further configured to pass the reliability information to a row decoder substantially simultaneously to passing the reliability information to a column decoder.

47. The system of claim 41, wherein the logic is included in at least one of a discrete logic circuit having logic gates for implementing logic functions upon data signals, an application specific integrated circuit having combinational logic gates, a programmable gate array, and a field programmable gate array.

48. The system of claim 41, wherein the logic includes software with parallel decoding functionality.

49. The system of claim 41, wherein the logic includes a row decoder and a column decoder.

50. The system of claim 41, wherein the logic is included in a computer readable medium.

51. The system of claim 41, wherein the logic is further configured to determine the reliability by calculating a result for the log likelihood ratio according to at least one of equations Λ(dⱼ)≈[(|R−\hat{D}|²−|R−D|²)/4](2dⱼ−1) and Λ(dⱼ)=[(R·D−R·\hat{D})/2](2dⱼ−1) for dⱼ ε{0,1}, wherein R includes a received noisy sequence, D includes a decided codeword after decoding, and \hat{D} includes a candidate codeword.

52. The system of claim 41, wherein the logic is further configured to substantially simultaneously pass the reliability determinations of the row symbols and the column symbols.

53. The system of claim 41, further including at least one of a processor, memory, and a threshold device that communicates with the logic in providing decoding functionality.

54. The system of claim 53, wherein the processor and the logic are located in separate devices.

55. The system of claim 53, wherein the processor and the logic are located in the same device.

56. A system for decoding product codes, the system comprising:
logic configured to pass reliability determinations of row symbols to decode a next column of symbols, wherein at a time corresponding to passing the reliability determinations of the row symbols the logic is further configured to pass reliability determinations of column symbols to decode a next row of symbols, wherein the row and the column decoding occur substantially simultaneously, wherein the reliability determinations are based at least in part on real number valued information received from the symbols.

57. The system of claim 56, wherein the symbols include at least one of real numbered values, real numbered voltage values, bit values, and byte values.

58. The system of claim 56, wherein the product codes include symbols encoded with error correcting codes formatted in a matrix of rows and columns.

59. The system of claim 56, wherein the logic is further configured to pass the reliability determinations for multiple iterations.

60. The system of claim 56, wherein the logic is included in at least one of a discrete logic circuit having logic gates for implementing logic functions upon data signals, an application specific integrated circuit having combinational logic gates, a programmable gate array, and a field programmable gate array.

61. The system of claim 56, wherein the logic includes software with parallel decoding functionality.

62. The system of claim 56, wherein the logic includes a row decoder and a column decoder.

63. The system of claim 56, wherein the logic is included in a computer readable medium.

64. The system of claim 56, wherein the logic is further configured to determine the reliability by calculating a result for the log likelihood ratio according to at least one of equations Λ(dⱼ)≈[(|R−\hat{D}|²−|R−D|²)/4](2dⱼ−1) and Λ(dⱼ)=[(R·D−R·\hat{D})/2](2dⱼ−1) for dⱼ ε{0,1}, wherein R includes a received noisy sequence, D includes a decided codeword after decoding, and \hat{D} includes a candidate codeword.

65. The system of claim 56, wherein the logic is further configured to substantially simultaneously pass the reliability determinations of the row symbols and the column symbols.

66. The system of claim 56, further including at least one of a processor, memory, and a threshold device that communicates with the logic in providing decoding functionality.

67. The system of claim 66, wherein the processor and the logic are located in separate devices.

68. The system of claim 66, wherein the processor and the logic are located in the same device.

69. A system for decoding product codes, the system comprising:
logic configured to receive symbols encoded with first parity information and second parity information, wherein the logic is further configured to decode the symbols using the first parity information while decoding the symbols using the second parity information.

70. A system for decoding product codes, the system comprising:
logic configured to pass reliability determinations, made while decoding symbols using first parity information, to use in decoding the symbols using second parity information, while substantially simultaneously passing the reliability determinations made, while decoding the symbols using the second parity information, to use in decoding the symbols using the first parity information, wherein the reliability determinations are based at least in part on real number valued information received from the symbols.
